(19) United States
(12) Patent Application Publication
(10) Pub. No.: US 2013/0252351 A1
(43) Pub. Date: Sep. 26, 2013

(54) FILM-FORMING FORMULATIONS FOR SUBSTRATE PRINTING

(71) Applicants: Inna TREGUB, San Jose, CA (US); Tane BOGHOZIAN, Sunnyvale, CA (US); Jesse DANIELZADEH, San Jose, CA (US); Ranjana SHAH, Sunnyvale, CA (US); Valerie GASSEND, San Carlos, CA (US); Ian MILLARD, Menlo Park, CA (US); Jianglong CHEN, Cupertino, CA (US)

(72) Inventors: Inna TREGUB, San Jose, CA (US); Tane BOGHOZIAN, Sunnyvale, CA (US); Jesse DANIELZADEH, San Jose, CA (US); Ranjana SHAH, Sunnyvale, CA (US); Valerie GASSEND, San Carlos, CA (US); Ian MILLARD, Menlo Park, CA (US); Jianglong CHEN, Cupertino, CA (US)

(73) Assignee: KATEEVA, INC, Menlo Park, CA (US)

(21) Appl. No.: 13/618,157

(22) Filed: Sep. 14, 2012

Related U.S. Application Data
(60) Provisional application No. 61/535,413, filed on Sep. 16, 2011.

(51) Int. Cl. H01L 51/00

(52) U.S. Cl. CPC H01L 51/0005
USPC 438/14; 118/300; 252/500; 252/301.16; 252/301.35; 438/46

(57) ABSTRACT

Film-forming formulations are provided that satisfy a plurality of criteria for inkjet printing, thermal printing, or both. Criteria for film-forming formulations are also provided for selecting vehicles, combinations of vehicles, and film-forming materials, based upon viscosity, surface tension, solubility, and properties of printed films formed by such formulations. Film-forming formulations useful in the fabrication of organic light emitting devices (OLEDs) are provided including formulations useful for the fabrication of OLED hole transport layers, hole injection layers, electron transport layers, electron injection layers, and emissive layers, of an OLED. Methods of evaluating formulations for suitability in inkjet printing, thermal printing, or both, are also provided.

### CROSS REFERENCE TO RELATED APPLICATIONS

This application claims priority from U.S. Application No. 61/535,413 filed Sep. 16, 2011, which is incorporated herein in its entirety by reference. This application references U.S. patent application Ser. No. 12/139,409, filed Jun. 13, 2008, and published Dec. 18, 2008, as U.S. Patent Application Publication No. US 2008/0308037 A1, which in turn claims priority to U.S. Provisional Patent Application No. 60/944,000 filed Jun. 14, 2007, each of which is incorporated herein in its entirety by reference.

### FIELD

This invention relates generally to methods and materials for formulating film-forming formulations suitable for use in printing processes, and film-forming formulations suited for use in deposition of layers used in the fabrication of organic light emitting devices (OLEDs).

### BACKGROUND

Flat panel displays and various forms of thin film electronic and/or optical devices involve the creation of precisely tailored structures on a substrate, often extending over a large area. Inkjet and thermal printing allow for creation of such structures.

There exists a need in the art for film-forming formulations, and methods to test film-forming formulations, that are suitable for use printing on substrates, especially for formulations that can be used for printing layers of materials that can be employed in the fabrication of OLEDs.

### SUMMARY

According to various embodiments of the present teachings, a film-forming formulation for inkjet printing is provided. The formulation is well suited for forming pixels on a substrate and can be useful for forming functional layers of an organic light emitting device (OLED). The formulation can comprise a film-forming material that is dissolved in a vehicle and stable in the vehicle. The film-forming material can be present in an amount of from about 0.1% by weight to about 10.0% by weight based on the total weight of the film-forming formulation. The vehicle can comprise a blend of at least two solvents that are miscible with one another, wherein each solvent is present in an amount of from about 1% by weight to about 99% by weight based on the total weight of the vehicle. The properties of the vehicle can differ from the properties of either solvent of the blend, and solvents can be blended to form a vehicle that is especially well-suited forming pixels on a substrate. The vehicle can be formulated to substantially completely evaporate after the formulation is inkjet-printed onto a substrate, leaving the film-forming material on the substrate in the form of a solid film. The film-forming formulation can have a viscosity and a surface tension at an inkjet jetting temperature, which enable consistent, reliable delivery from an inkjet printhead. By using a specially selected blend of solvents, the resulting solid film exhibits less of a coffee ring effect than the coffee ring effect that would be caused by inkjet-printing substantially the same formulation onto the same substrate but wherein the formulation comprises only a single one of the at least two solvents. Accordingly, the film-forming formulations of the present teachings can reduce, minimize, eliminate, and/or overcome the problem of the coffee ring effect that has plagued previous pixel printing processes. In some embodiments, film-forming formulations are provided that are suitable for thermal printing.

The present teachings also provide a method for evaluating a film-forming formulation to determine whether the formulation would be suitable for an inkjet printing process. The method can involve determining whether the film-forming material is substantially soluble in the vehicle, determining whether the film-forming formulation exhibits a surface tension of from about 28 dynes/cm to about 40 dynes/cm, and determining whether the film-forming formulation exhibits a viscosity of from about 1.0 centipoise to about 14 centipoise at inkjet jetting temperatures. The method can further involve inkjet printing the film-forming formulation and determining whether the vehicle substantially completely evaporates while the film-forming material forms a solid film, and whether the film-forming material has formed a film of substantially uniform thickness. If the method determines that the film-forming formulation meets these criteria, then the film-forming formulation can then be inkjet-printed, used to form pixels, labeled, packaged, sold, shipped, or subject to a combination thereof.

Examples of film-forming formulations for printing OLED layers are also provided, as are layers for OLEDs.

### BRIEF DESCRIPTION OF THE DRAWINGS

Unless otherwise noted, the figures presented herein are schematic and not to scale, and the relative dimensions of components depicted in various figure are also schematic and not to scale. The drawings are intended to illustrate, not limit, the present teachings.

FIG. 1 is a microphotograph of a pixel formed from a film-forming formulation that has been inkjet-printed onto an indium tin oxide pixelated substrate to form a pixel.

FIG. 2 is a microphotograph of a pixel formed from a film-forming formulation that has been inkjet-printed onto an indium tin oxide pixelated substrate to form a pixel.

FIG. 3 is a microphotograph of a pixel formed from a film-forming formulation that has been inkjet-printed onto an indium tin oxide pixelated substrate to form a pixel.

FIG. 4 is a microphotograph of a pixel formed from a film-forming formulation, according to an embodiment of the present teachings, which has been inkjet-printed onto an indium tin oxide pixelated substrate to form a pixel.

FIG. 5 is a microphotograph of a pixel formed from a film-forming formulation, according to an embodiment of the present teachings, which has been inkjet-printed onto an indium tin oxide pixelated substrate to form a pixel.

FIG. 6 is a microphotograph of a pixel formed from a film-forming formulation, according to an embodiment of the present teachings, which has been inkjet-printed onto an indium tin oxide pixelated substrate to form a pixel.

FIG. 7 is a schematic representation of an exemplary thermal printhead having a dispensing mechanism that can be used according to various embodiments of the present teachings.

FIG. 8 is a schematic representation of an exemplary printhead having a piezo-electric dispensing mechanism that can be used according to various embodiments of the present teachings.

### DETAILED DESCRIPTION

According to various embodiments of the present teachings, a film-forming formulation is provided for inkjet printing. The formulation comprises a film-forming material dissolved in a vehicle. The film-forming material is stable in the vehicle and is present in an amount of from about 0.1% by weight to about 10.0% by weight based on the total weight of the film-forming formulation. In some cases, the film-forming material can be present in an amount of from about 0.2% by weight to about 3% by weight based on the total weight of the film-forming formulation. The vehicle can comprise a blend of at least two solvents that are miscible with one another, each solvent being present in an amount of from about 1% by weight to about 99% by weight based on the total weight of the vehicle. The vehicle is formulated to substantially completely evaporate after application to a substrate, for example, by inkjet printing. The film-forming material can form a solid film. The film-forming formulation can have a viscosity and a surface tension at inkjet jetting temperatures, for example, at 25° C., that enable delivery from an inkjet printhead. In some cases, consistent, reliable delivery can be achieved at room temperature. The vehicle can exhibit an evaporation rate that differs from the evaporation rate of any one of the at least two solvents alone. The vehicle can exhibit properties that provide a substantially uniformly thick film of the film-forming material.

In some embodiments, the film-forming material comprises one or more components useful in forming at least one of a hole transport layer, a hole injection layer, an electron transport layer, an electron injection layer, and an emissive layer, of an organic light-emitting device. The film-forming material can comprise no more than a single organic compound. The film-forming formulation can exhibit a surface tension of 40.0 dynes/cm or lower, for example, at 25° C. In some cases, the film-forming formulation can exhibit a surface tension of from about 30 dynes/cm to about 37 dynes/cm at 25°, for example, a surface tension of from about 34 dynes/cm to about 36 dynes/cm at 25° C. The film-forming formulation can exhibit a viscosity of from about 1.0 centipoise to about 14 centipoise at 25° C., for example, a viscosity of from about 4.0 centipoise to about 10 centipoise at 25° C. The at least two solvents can comprise at least two organic solvents. Many solvents and blends of solvents that can be used are described in more detail below. According to various embodiments, the vehicle can comprise a mixture of organic solvents and the film-forming material can comprise organic small molecules useful for forming an emissive layer of an organic light emitting device.

According to various embodiments of the present teachings, each of the at least two solvents can be present in an amount of 30% by weight or more based on the total weight of the vehicle. In addition to the at least two solvents, the vehicle can comprise a third solvent, or a mixture of additional solvents, that comprise up to 30% by weight of the vehicle based on the total weight of the vehicle.

In some cases, the at least two solvents are miscible with water and the vehicle can further comprise water and optionally a surfactant. The surfactant can comprise methicone. The surfactant can comprise a non-ionic fluorosurfactant present in an amount of from about 0.001% by weight to about 1.0% by weight based on the total weight of the vehicle, or from 0.05% by weight to about 0.5% by weight. According to various embodiments, exemplary surfactants that can be used include fluorosurfactants available from E. I. du Pont de Nemours and Company of Wilmington, Del., sold under the trade names Zonyl® FS 1033D, Zonyl® FS 1176, Zonyl® FSG, Zonyl® FS-300, Zonyl® FSN, Zonyl® FSH, Zonyl® FSN, Zonyl® FSO, Zonyl® FSN-100, Zonyl® FSO-100, Zonyl® FSH, Zonyl® FSN, Zonyl® FSO, Zonyl® FSH, Zonyl® FSN, Zonyl® FSO, Zonyl® FS 500, Zonyl® FS 510, Zonyl® FSJ, Zonyl® FS-610, Zonyl® 9361, Zonyl® FSA, FSP, FSE, FSJ, Zonyl® FSP, Zonyl® 9361, Zonyl® FSE, Zonyl® FSA, Zonyl® UR, Zonyl® 8867L, Zonyl® FSG, Zonyl® 8857A, Foraperle® 225, Forafac® 1268, Forafac® 1157, Forafac® 1183, Zonyl® 8929B, Zonyl® 9155, Zonyl® 9815, Zonyl® 9933LX, Zonyl® 9938, Zonyl® PFBI, Zonyl® PFBEI, Zonyl® PFBE, Zonyl® PFHI, Zonyl® BA, Zonyl® PFHEI, Zonyl® TM, Zonyl® 8932, Zonyl® 7910, Zonyl® 7040, Foraperle® 321/325, Zonyl® 9464, Zonyl® NF, Zonyl® RP, Zonyl® 321, Zonyl® 8740, Zonyl® 225, Zonyl® 227, Zonyl® 9977, Zonyl® 9027, Zonyl® 9671, Zonyl® 9338, and Zonyl® 9582.

According to various embodiments, exemplary surfactants that can be used include methicones available from E. I. du Pont de Nemours and Company of Wilmington, Del., sold under the trade names Capstone® ST-500, Capstone® ST-300, Capstone® ST-200, Capstone® ST-110, Capstone® P-640, Capstone® P-623, Capstone® P-620, Capstone® P-600, Capstone® FS-10, Capstone® FS-17, Capstone® FS-22, Capstone® FS-30, Capstone® FS-31, Capstone® FS-3100, Capstone® FS-34, Capstone® FS-35, Capstone® FS-50, Capstone® FS-51, Capstone® FS-60, Capstone® FS-61, Capstone® FS-63, Capstone® FS-64, Capstone® FS-64, Capstone® FS-65, Capstone® FS-66, Capstone® FS-81, Capstone® FS-83, Capstone® LPA, Capstone® 1460, Capstone® 1157, Capstone® 1157D, Capstone® 1183, Capstone® CPS, Capstone® E, Capstone® LMC, Capstone® CP, Capstone® PSB, Capstone® 4-I, Capstone® 42-I, Capstone® 42-U, Capstone® 6-I, Capstone® 62-AL, Capstone® 62-I, Capstone® 62-MA, Capstone® TC, Capstone® TR, and Capstone® TS.

According to various embodiments, exemplary surfactants that can be used include the following surfactants available from Dow Corning Corporation of Washington, D.C., sold under the trade names DOW CORNING® BY 11-030, DOW CORNING® BY 25-337, DOW CORNING® ES-5226 DM, DOW CORNING® ES-5612, DOW CORNING® RM 2051, DOW CORNING® 5225C, DOW CORNING® 9011, DOW CORNING® CE-8411, XIAMETER® OFX-0190, XIAMETER® OFX-0193, XIAMETER® OFX-5220, XIAMETER® OFX-5324, XIAMETER® OFX-5330, XIAMETER® OFX-1005, XIAMETER® OFX-5329 D, DOW CORNING® CE 8401, DOW CORNING® 5200, and DOW CORNING® EMULSIFIER 10.

According to various embodiments, exemplary surfactants that can be used include the following surfactants available from Botanigenics, Inc. of Northridge, Calif., sold under the trade names Botanisil® AD-13, AM-14, ATC-21, BPD-100, CD-80, CD-90, CE-35, CM-12, CM-13, CM-70, CP-33, CPM-10, CS-50, CTS-45, DM-60M, DM-85, DM-90, DM-91, DM-92, DM-93, DM-94, DM-95, DM-96, DM-97, DTS-13, DTS-35, GB-19, GB-20, GB-23, GB-25, GB-35, L-23, ME-10, ME-12, PSS-150, PT-100, S-18, S-19, S-20, TSA-16, and TSS-1.

According to various embodiments, exemplary surfactants that can be used include the following surfactants available from BYK-Chemie GmbH of Wesel, Germany, sold under the trade names BYK®-346, BYK®-333, BYK®-381, BYK-DYNWET-800, BYK®-1740, BYK®-012, BYK®-016, BYK®-410, BYK®-420, BYK®-067 A, BYK®-066 N, BYK®-052, BYK®-4100, and BYK®-394.

According to various embodiments, exemplary surfactants that can be used include the following surfactants available from Air Products and Chemicals, Inc. of Allentown, Pa., sold under the trade names Surfynol® 420, 440, 104, and SE-F.

When using vehicles that are miscible with water, the film-forming material can comprise a polymeric material useful for forming a hole transport layer or a hole injection layer of an organic light emitting device. In exemplary embodiments, the film-forming material comprises one or more of poly (3,4-ethylenedioxythiopene), poly(ethylene dioxythiophene)/poly(styrene sulfonic acid) (PEDOT/PSS), an aqueous solution of polyaniline/camphor sulfonic acid (PANI/CSA), PTPDES, Et-PIT-DEK, PPBA, a combination thereof, or the like. Other film-forming materials that can be included in and printed according to various embodiments of the present teachings include those described in U.S. Pat. No. 7,820,231 B2, which is incorporated herein in its entirety by reference.

According to various embodiments, the film-forming material can be formulated in such a way that it forms a pixel when inkjet-printed onto a substrate, for example, onto a pixelated substrate or a substrate provided with a pattern of banks for receiving and retaining pixel-forming or film-forming material. The formulations and methods of the present teachings can greatly reduce, minimize, or eliminate the coffee ring effect that often occurs when pixel-forming materials are deposited in a single-component-vehicle formulation. The film-forming material can have less of a coffee ring effect compared to the coffee ring effect that is caused by inkjet-printing substantially the same formulation onto the same substrate but wherein the formulation comprises only a single one of the at least two solvents. The coffee ring effect, pile-up of film-forming material, pixel banks, pinning in pixel banks, and methods of inkjet printing pixels are described in more detail in U.S. Pat. No. 6,878,312 B2, in U.S. Pat. No. 7,022,534, in U.S. Patent Application Publication No. US 2008/0135804 A1, in U.S. Patent Application Publication No. US 2011/0180787 A1, in Müller-Buschbaum et al., Solvent-Induced Surface Morphology of Thin Polymer Films, Macromolecules, 34 (2001), pages 1369-1375, and in Tekin et al., Ink-jet printing of polymers—from single dots to thin film libraries, J. Mater. Chem., 14 (2004), pages 2627-2632, each of which is herein incorporated in its entirety by reference.

According to various embodiments of the present teachings, the film-forming formulation is inert with respect to the inkjet printhead. In some cases, the film-forming formulation does not dry on the inkjet printhead within 10 minutes or less after printing, for example, within 5 minutes after printing or within 2 minutes after printing. Such drying properties enable a printhead to be blotted, cleaned, sealed, closed, or protected within a reasonable time after printing, without a residue forming on the printhead.

According to various embodiments of the present teachings, a method is provided that involves inkjet printing the film-forming formulation onto a pixelated substrate to form a plurality of wet pixels. The vehicle in the wet pixels can then be made to evaporate, for example, by heating, by using an inert gas stream, or simply by evaporation over a period of time. The vehicle in the wet pixels can be made to evaporate thus forming a plurality of dry pixels. The plurality of dry pixels can have a substantially uniform thickness and exhibit less of a coffee ring effect than the coffee ring effect that would be caused by inkjet-printing substantially the same formulation onto the same substrate but wherein the formulation comprises only a single one of the at least two solvents. By a “substantially uniform thickness” what is meant is that each pixel of the plurality of dry pixels can have a ratio of minimum thickness to maximum thickness of almost 1 to 1, for example, of 0.9 or greater to 1. In some cases, each of the plurality of dry pixels can have a ratio of minimum thickness to maximum thickness of 0.95 or greater to 1. In some embodiments, at least 75%, at least 80%, at least 85%, at least 90%, at least 95%, or at least 99% of all of the dry pixels formed by the film-forming material have a ratio of minimum thickness to maximum thickness of almost 1 to 1, for example, of 0.9 or greater to 1 or 0.95 or greater to 1. The plurality of dry pixels can be part of a pixelated substrate that comprises an indium tin oxide glass material. The plurality of pixels can comprise at least one of a hole transport layer, a hole injection layer, an emissive layer, a combination thereof, or the like, of an organic light-emitting device.

According to various embodiments of the present teachings, a method is provided for evaluating a film-forming formulation to determine whether the formulation would be suitable for an inkjet printing process, and if so, how suitable. The method can comprise formulating a film-forming formulation comprising a film-forming material dissolved in a vehicle. To receive a favorable evaluation, the film-forming material should be stable in the vehicle and should be present in an amount of from about 0.1% by weight to about 10.0% by weight based on the total weight of the film-forming formulation, for example, from about 0.1% by weight to about 5.0% by weight or from about 0.2% by weight to about 3.0% by weight. The vehicle should comprise a blend of at least two solvents that are miscible with one another. Each solvent should be present in an amount of from about 1% by weight to about 99% by weight based on the total weight of the vehicle, for example, from about 5% by weight to about 75.0% by weight, from about 10% by weight to about 60.0% by weight, or from about from about 30% by weight to about 50.0% by weight. Moreover, the method for evaluating the film-forming formulation should determine whether the film-forming material is substantially soluble in the vehicle, and if it is not, then the film-forming formulation can be considered unacceptable. The method for evaluating the film-forming formulation should determine whether the film-forming formulation exhibits a surface tension of from about 28 dynes/cm to about 40 dynes/cm at 25° C., for example, from about 30 dynes/cm to about 37 dynes/cm at 25° C., and if it does not, then the film-forming formulation can be considered unacceptable. The method for evaluating the film-forming formulation should determine whether the film-forming formulation exhibits a viscosity of from about 1.0 centipoise to about 14 centipoise at inkjet jetting temperatures such as 25° C., for example, from about 4.0 centipoise to about 10 centipoise at 25° C., and if it does not, then the film-forming formulation can be considered unacceptable. The method for evaluating the film-forming formulation should determine whether the vehicle substantially completely evaporates while the film-forming material forms a solid film, and if it does not, then the film-forming formulation can be considered unacceptable. The method for evaluating the film-forming formulation should determine whether the film-forming material can form a film of substantially uniform thickness, and if it does not, then the film-forming formulation can be considered unacceptable. If the aforementioned determinations are made and the film-forming formulation meets these criteria, then the method for evaluating the film-forming formulation can identify the film-forming formulation as suitable for an inkjet printing process. If determined to be suitable, the film-forming formulation can then be inkjet-printed, used to form pixels, labeled, packaged, sold, shipped, or subject to a combination thereof.

The method for evaluating a film-forming formulation for an inkjet printing process can further comprise subjecting the film-forming formulation to an inkjet printing process. The printing can be used to make one or more of the determinations, for example, whether the vehicle substantially completely evaporates while the film-forming material forms a solid film, or whether the film-forming material forms a solid film, or whether the film-forming material can acceptably form a layer of pixels on a substrate. The method can determine whether each pixel can exhibit a substantially uniform thickness and less of a coffee ring effect than would be exhibited if substantially the same formulation were inkjet-printed onto the same substrate but wherein the formulation comprises only a single one of the at least two solvents. The method for evaluating the film-forming formulation can comprise inkjet printing the film-forming formulation and evaporating the vehicle to see whether the formulation can be used to form an emissive layer, a hole transport layer, a hole injection layer, or the like, for an organic light emitting device.

Other determinations that can be made for the purpose of considering whether a film-forming formulation would be acceptable include, but are not limited to, one or more determinations of whether: the film-forming material is present in an amount of from about 0.1% by weight to about 3.0% by weight based on the total weight of the film-forming formulation; whether the film-forming formulation exhibits a surface tension of from about 35 dynes/cm to about 37 dynes/cm; whether the film-forming formulation exhibits a viscosity of from about 4.0 centipoise to about 10 centipoise; and whether the film-forming material forms a film that has, or a certain percentage of dry pixels that have, a ratio of minimum thickness to maximum thickness of 0.9 or greater to 1, for example, 0.95 or greater to 1.

Solvent blends that have been found to meet the criteria for good inkjet printing vehicles include blends of two, three, or more solvents. In some cases, the at least two solvents that are used in the vehicle blend can comprise two or more solvents selected from alkoxy alcohol, alkyl alcohol, alkyl benzene, alkyl benzoate, alkyl naphthalene, amyl octanoate, anisole, aryl alcohol, benzyl alcohol, butyl benzene, butyrophenon, cis-decalin, dipropylene glycol methyl ether, dodecyl benzene, mesitylene, methoxy propanol, methylbenzoate, methyl naphthalene, methyl pyrrolidinone, phenoxy ethanol, 1,3-propanediol, pyrrolidinone, trans-decalin, and valerophenon.

In some embodiments, the vehicle comprises a blend of benzyl alcohol and butyl benzene, a blend of benzyl alcohol and anisole, a blend of benzyl alcohol and mesitylene, a blend of butyl benzene and anisole, a blend of butyl benzene and mesitylene, a blend of anisole and mesitylene, a blend of dodecyl benzene and cis-decalin, a blend of dodecyl benzene and benzyl alcohol, a blend of dodecyl benzene and butyl benzene, a blend of dodecyl benzene and anisole, a blend of dodecyl benzene and mesitylene, a blend of cis-decalin and benzyl alcohol, a blend of cis-decalin and butyl benzene, a blend of cis-decalin and anisole, a blend of cis-decalin and mesitylene, a blend of trans-decalin and benzyl alcohol, a blend of trans-decalin and butyl benzene, a blend of trans-decalin and anisole, a blend of trans-decalin and mesitylene, a blend of methylpyrrolidinone and anisole, a blend of methylbenzoate and anisole, a blend of methyl pyrrolidinone and methyl naphthalene, a blend of methylpyrrolidinone and methoxy propanol, a blend of methylpyrrolidinone and phenoxy ethanol, a blend of methylpyrrolidinone and amyl octanoate, a blend of methylpyrrolidinone and trans-decalin, a blend of methylpyrrolidinone and mesitylene, a blend of methylpyrrolidinone and butyl benzene, a blend of methyl pyrrolidinone and dodecyl benzene, a blend of methylpyrrolidinone and benzyl alcohol, a blend of anisole and methyl naphthalene, a blend of anisole and methoxy propanol, a blend of anisole and phenoxy ethanol, a blend of anisole and amyl octanoate, a blend of methylbenzoate and methyl naphthalene, a blend of methylbenzoate and methoxy propanol, a blend of methylbenzoate and phenoxy ethanol, a blend of methylbenzoate and amyl octanoate, a blend of methylbenzoate and cis-decalin, a blend of methylbenzoate and trans-decalin, a blend of methylbenzoate and mesitylene, a blend of methylbenzoate and butyl benzene, a blend of methylbenzoate and dodecyl benzene, a blend of methylbenzoate and benzyl alcohol, a blend of methyl naphthalene and methoxy propanol, a blend of methyl naphthalene and phenoxy ethanol, a blend of methyl naphthalene and amyl octanoate, a blend of methyl naphthalene and cis-decalin, a blend of methyl naphthalene and trans-decalin, a blend of methyl naphthalene and mesitylene, a blend of methyl naphthalene and butyl benzene, a blend of methyl naphthalene and dodecyl benzene, a blend of methyl naphthalene and benzyl alcohol, a blend of methoxy propanol and phenoxy ethanol, a blend of methoxy propanol and amyl octanoate, a blend of methoxy propanol and cis-decalin, a blend of methoxy propanol and trans-decalin, a blend of methoxy propanol and mesitylene, a blend of methoxy propanol and butyl benzene, a blend of methoxy propanol and dodecyl benzene, a blend of methoxy propanol and benzyl alcohol, a blend of phenoxy ethanol and amyl octanoate, a blend of phenoxy propanol and mesitylene, a blend of phenoxy propanol and butyl benzene, a blend of phenoxy propanol and dodecyl benzene, a blend of phenoxy propanol and benzyl alcohol, a blend of amyl octanoate and cis-decalin, a blend of amyl octanoate and trans-decalin, a blend of amyl octanoate and mesitylene, a blend of amyl octanoate and butyl benzene, a blend of amyl octanoate and dodecyl benzene, a blend of amyl octanoate and benzyl alcohol, or a combination thereof. In some embodiments, each of the solvents in each of the blends listed above is present in an amount of at least 5% by weight based on the total weight of the vehicle, for example, at least 10% by weight, at least 15% by weight, at least 20% by weight, at least 25% by weight, at least 30% by weight, at least 35% by weight, or at least 40% by weight. In some embodiments, each of the solvents in each of the blends listed can comprise 50% by weight of the vehicle based on the total weight of the vehicle.

According to various embodiments, the vehicle comprises a blend of valerophenon and dipropyleneglycol methyl ether, a blend of valerophenon and butyrophenon, a blend of dipropyleneglycol methyl ether and butyrophenon, a blend of dipropyleneglycol methyl ether and 1,3-propanediol, a blend of butyrophenon and 1,3-propanediol, a blend of dipropyleneglycol methyl ether, 1,3-propanediol, and water, or a combination thereof. In some embodiments, each of the solvents in each of the blends listed above is present in an amount of at least 20% by weight based on the total weight of the vehicle, for example, at least 25% by weight, at least 30% by weight, at least 35% by weight, at least 40% by weight, or at least 45% by weight.

In some embodiments, a blend of three, four, five, or more solvents can be used for the vehicle. For example, the vehicle can comprise a blend of three, four, five, or more solvents selected from pyrrolidinone, methylpyrrolidinone, anisole, alkyl benzoate, methylbenzoate, alkyl naphthalene, methyl naphthalene, alkoxy alcohol, methoxy propanol, phenoxy ethanol, amyl octanoate, cis-decalin, trans-decalin, mesitylene, alkyl benzene, butyl benzene, dodecyl benzene, alkyl alcohol, aryl alcohol, benzyl alcohol, butyrophenon, dipropylene glycol methyl ether, valerophenon, and 1,3-propanediol. As an example, the vehicle can comprise three or more solvents selected from cis-decalin, trans-decalin, benzyl alcohol, butyl benzene, anisole, mesitylene, and dodecyl benzene. In some embodiments, dodecyl benzene is present in an amount of from about 0% by weight to about 50% by weight, or from about 10% by weight to about 40% by weight, or about 30% by weight, based on the total weight of the vehicle. In some embodiments, cis-decalin is present in an amount of from about 10% by weight to about 40% by weight, or from 20% by weight to about 30% by weight, or about 25% by weight, based on the total weight of the vehicle. In some embodiments, trans-decalin is present in an amount of from about 10% by weight to about 40% by weight, or from 20% by weight to about 30% by weight, or about 25% by weight, based on the total weight of the vehicle. In some embodiments, a mixture of cis-decalin and trans-decalin is present in the vehicle and the mixture is present in an amount of from about 10% by weight to about 40% by weight, or from 20% by weight to about 30% by weight, or about 25% by weight, based on the total weight of the vehicle. In some embodiments, benzyl alcohol is present in an amount of from about 20% by weight to about 50% by weight, or from about 30% by weight to about 40% by weight, or about 35% by weight, based on the total weight of the vehicle. In some embodiments, butyl benzene is present in an amount of from about 0% by weight to about 20% by weight, or from about 5% by weight to about 15% by weight, or about 10% by weight, based on the total weight of the vehicle. In some embodiments, anisole is present in an amount of from about 5% by weight to about 40% by weight, or from about 10% by weight to about 30% by weight, or about 20% by weight, based on the total weight of the vehicle. In some embodiments, mesitylene is present in an amount of from about 0% by weight to about 20% by weight, or from about 5% by weight to about 15% by weight, or about 10% by weight, based on the total weight of the vehicle.

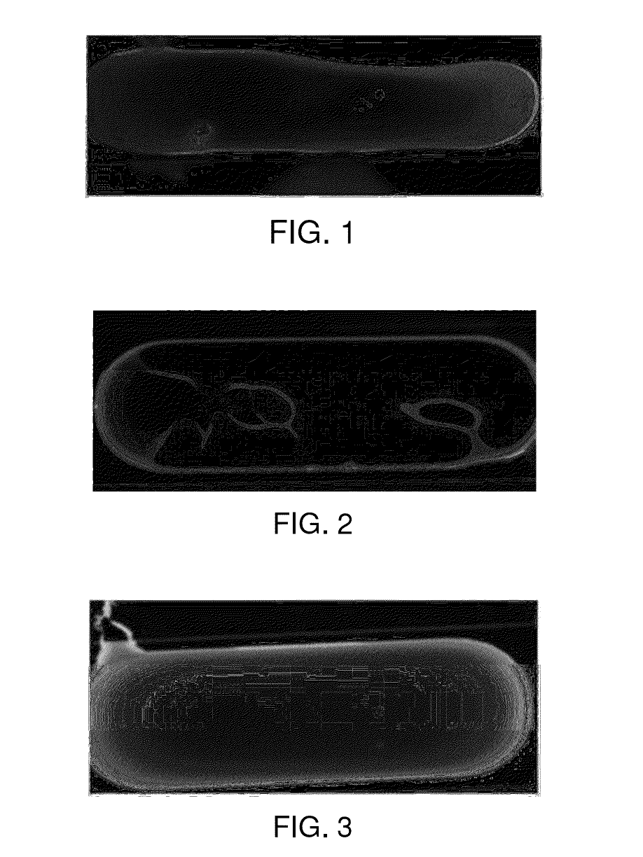

As demonstrated by a comparison of FIGS. 1-3 to FIGS. 4-6, and as described below, the vehicles and film-forming formulations of the present teachings exhibit excellent solubility for the film-forming materials contained therein, exhibit no phase separation problems, exhibit good pinning properties within pixel banks formed on a substrate, and exhibit good confinement within pixel banks thereby reducing or eliminating the potential for overspill.

FIG. 1 is a microphotograph of a pixel formed from a film-forming formulation that has been inkjet-printed into a pixel bank formed on an indium tin oxide substrate, to form a pixel. As can be seen, the pinning lines are not straight and the pixel displayed irregularities resulting from phase separation of the formulation. The formulation used to form the dry pixel shown in FIG. 1 did not exhibit good dissolution of the film-forming material in the vehicle. The film-forming material was not stable in the vehicle and the formulation did not provide a substantially uniformly thick film of the film-forming material.

FIG. 2 is a microphotograph of a pixel formed from a film-forming formulation that has been inkjet-printed into a pixel bank formed on an indium tin oxide substrate, to form a pixel. As can be seen, the pinning lines are not very straight and the pixel displayed irregularities resulting from phase separation of the formulation. The formulation used to form the dry pixel shown in FIG. 2 did not exhibit good dissolution of the film-forming material in the vehicle and the film-forming material was not stable in the vehicle. The pinning line lead was irregular, leading to pile-up of the film-forming formulation at the wall of the pixel bank. Consequently, the dried pixel resulting from the drying of the vehicle exhibited a non-uniform thickness, especially at the edges of the pixel where it meets the bank.

FIG. 3 is a microphotograph of a pixel formed from a film-forming formulation that has been inkjet-printed into a pixel bank formed on an indium tin oxide substrate, to form a pixel. At the upper left of the microphotograph an overspill can be seen, which resulted from an improper viscosity and/or surface tension of the film-forming formulation. The formulation did not exhibit good pinning within the pixel bank and thus would not be a good candidate for inkjet printing pixels.

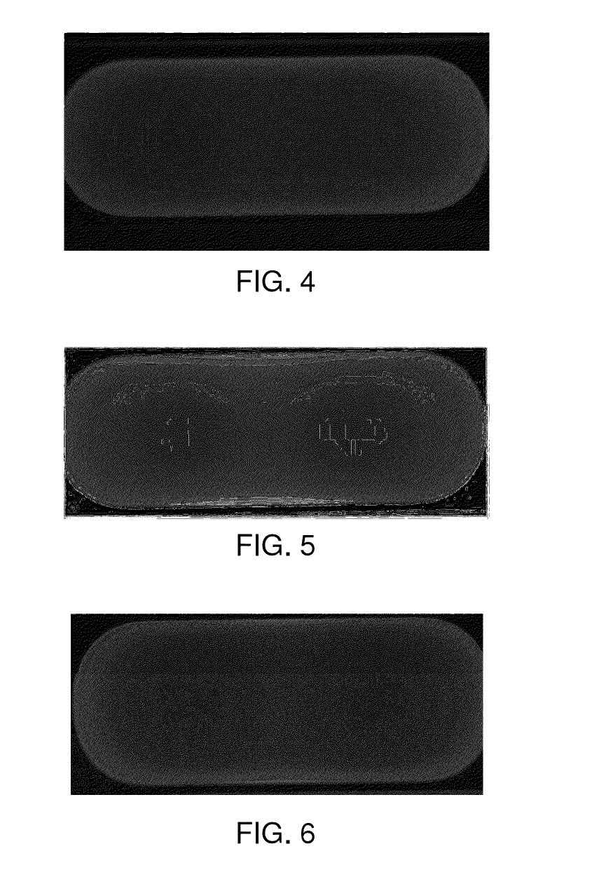

FIGS. 4-6 are microphotographs of pixels formed from film-forming formulations, according to the present teachings, that have been inkjet-printed into respective pixel banks formed on indium tin oxide substrates. Each of FIGS. 4-6 shows a pixel exhibiting good pinning, uniform dried pixel thickness, no phase separation, and no overspill. The formulations that were used to form the pixels shown in FIGS. 4-6 can be considered well-suited for inkjet printing pixels.

According to various embodiments of the present teachings, a film-forming formulation is provided that exhibits good properties not only for inkjet printing, but also for thermal printing. The formulation comprises a film-forming material dissolved or dispersed in a vehicle. The film-forming material has an evaporation temperature or a sublimation temperature and is stable in the vehicle. The film-forming material can be present in an amount of from about 0.1% by weight to about 10.0% by weight based on the total weight of the film-forming formulation. The vehicle has a maximum boiling point that is substantially lower than the evaporation or sublimation temperature of the film-forming material. The vehicle has high purity and the maximum boiling point and purity are such that when heated to a temperature below or equal to the maximum boiling point of the vehicle, the vehicle substantially completely and rapidly evaporates while the film-forming material remains stable. The vehicle is inert with respect to inkjet and/or thermal printing printhead materials. The film-forming formulation has a viscosity and a surface tension at inkjet jetting temperatures that enable reliable delivery from an inkjet printhead while leaving little or no residue on the printhead. Furthermore, the formulation can exhibit properties that enable it to leave little or no residue on a thermal printing printhead after thermal printing.

The film-forming material can comprise an ink, for example, an ink comprising an OLED organic material. In some embodiments, an emissive layer (EML), also referred to herein as an emitting layer or a emission layer, is formed. To form an EML, an ink can be used that comprises a single material with EML properties or a mixture of one or more host materials and optionally at least one dopant. The dopant can be present in an amount of from about 0% by weight to about 50% by weight based on the total weight of the host. The host can be present in an amount of from about 0.01% by weight to about 20% by weight based on the total weight of the film-forming formulation, for example, from about 0.4% by weight to about 20% by weight, or from about 0.4% by weight to about 10% by weight. The film-forming material can comprise one or more components useful in forming at least one of a hole transport layer, a hole injection layer, an electron transport layer, an electron injection layer, and an emissive layer, of an organic light-emitting device. In some embodiments, the film-forming material consists of a single organic compound. The film-forming material can be present in an amount of from about 0.5% by weight to about 3% by weight, or from about 1% by weight to about 3% by weight, based on the total weight of the film-forming formulation.

Good film-forming properties can be achieved with the present formulations when the maximum boiling point of the vehicle is at least 50° C. lower than the evaporation or sublimation temperature of the film-forming material, for example, at least 55° C. lower, at least 60° C. lower, at least 65° C. lower, or at least 70° C. lower. The vehicle can be highly pure such that it contains 2000 ppm or less in impurities, by weight, based on the total weight of the vehicle. The impurities can comprise liquid organic contaminants having boiling points that are higher than the maximum boiling point of the vehicle.

The film-forming formulation can exhibit a surface tension is from about 28 dynes/cm to about 40 dynes/cm at 25° C., for example, from about 33 dynes/cm to about 39 dynes/cm at 25° C., or from about 35 dynes/cm to about 37 dynes/cm at 25° C. The viscosity of the formulation at inkjet jetting temperatures can be from about 1.0 centipoise to about 15 centipoise at 25° C., for example, from about 2.0 centipoise to about 12 centipoise, or from about 4.0 centipoise to about 10 centipoise, at 25° C. Inkjet jetting temperatures useful for measuring viscosity can be room temperature, or about 25° C., or any other suitable inkjet jetting temperature. The film-forming material can be substantially soluble in the vehicle, in some embodiments, and substantially insoluble in the vehicle in other embodiments. Ink compositions, pigments, or combinations thereof can be used in the formulations.

The film-forming formulation can be formulated to leave little or no residue in the pores of a thermal printing printhead that comprises pores. By little or no residue, what is meant is, after thermal printing, the thermal printing printhead can be wetted by the film-forming formulation, heated to evaporate the vehicle, and heated to print the dried film-forming material, for at least 50,000 cycles without clogging the pores. Microscopic examination, for example, at 20× magnification, can be used to visually inspect for residue and/or residue build-up on the printhead.

According to various embodiments of the present teachings, a film-forming formulation for inkjet and/or thermal printing is provided that comprises a film-forming material comprising at least one OLED compound dissolved in a vehicle. The film-forming material can comprise, for example, an ink. The film-forming material has an evaporation or a sublimation temperature and can be present in an amount of from about 0.1% by weight or 0.5% by weight to about 5.0% by weight based on the total weight of the film-forming formulation, for example, from about 0.2% by weight to about 3% by weight, from about 1% by weight to about 3% by weight, or about 2% by weight, based on the total weight of the film-forming formulation. In some embodiments, the film-forming material is substantially soluble in the vehicle, for example, whereby greater than 1% of the material dissolves in the vehicle at room temperature.

For formulations wherein the film-forming material is soluble in the vehicle, the vehicle can have a maximum boiling point that is at least 50° C. lower than the evaporation or sublimation temperature of the film-forming material, for example, at least 55° C. lower, at least 60° C. lower, at least 65° C. lower, or at least 70° C. lower. The film-forming formulation can have a surface tension of from about 28 dynes/cm to about 40 dynes/cm, for example, from about 33 dynes/cm to about 39 dynes/cm, or from about 35 dynes/cm to about 37 dynes/cm. The film-forming formulation can have a viscosity of from about 1.0 centipoise to about 15 centipoise, for example, from about 2.0 centipoise to about 12 centipoise, or from about 4.0 centipoise to about 10 centipoise. The film-forming formulation can be substantially pure such that when heated to a temperature that is lower than the evaporation or sublimation temperature of the film-forming material the vehicle substantially completely evaporates while the film-forming material remains stable. The film-forming material can consist of or consist essentially of a single organic compound. The film-forming material can comprise at least one dopant and a host, the at least one dopant can be present in an amount of from about 1% by weight to about 25% by weight based on the total weight of the film-forming material, while the host can be present in an amount of from about 75% by weight to about 99% by weight based on the total weight of the film-forming material. In some embodiments, the at least one dopant can be present in an amount of from about 2% by weight to about 20% by weight based on the total weight of the film-forming material, while the host can be present in an amount of from about 80% by weight to about 98% by weight based on the total weight of the film-forming material. In some embodiments, the film-forming material consists of or consists essentially of the host and the at least one dopant.

For formulations wherein the film-forming material is soluble in the vehicle, different hosts and/or dopants that can be included in the formulations include the hosts and dopants described in U.S. Pat. No. 7,304,428 B2 to Ghosh et al., which is incorporated herein in its entirety by reference. The dopant can be present in an amount of from about 2% by weight to about 10% by weight based on the total weight of the film-forming material. In embodiments wherein the film-forming material is soluble in the vehicle, the film-forming formulation can exhibit a viscosity of from about 4.0 centipoise to about 12.0 centipoise at 25° C., a surface tension is from about 35 dynes/cm to about 37 dynes/cm at 25° C., or a combination of these properties.

For formulations wherein the film-forming material is soluble in the vehicle, and in some other embodiments, the vehicle can comprise an organic solvent, pyrrolidinone, methyl pyrrolidinone, anisole, methylbenzoate, methyl naphthalene, trimethylbenzene, or a combination thereof. The vehicle can comprise an alkoxy alcohol having from about 4 to about 10 carbon atoms. The vehicle can comprise methyl naphthalene, phenoxyethanol, amyl octanoate, benzyl alcohol, pyrrolidinone, mineral oil, or a combination thereof. In an exemplary embodiment, the vehicle comprises tetrahydronapthalene and dipropylene glycol methyl ether. In another example, the vehicle comprises phenoxyethanol and butyrophenone. In another example the vehicle comprises two or more of methyl naphthalene, benzyl alcohol, phenoxy ethanol, and pyrrolidinone. In another example, the vehicle comprises pyrrolidinone, methylpyrrolidinone, anisole, methylbenzoate, methyl naphthalene, or a combination thereof.

When used with a soluble film-forming material, the vehicle can exhibit high purity, for example, it can contain 2000 ppm or less of impurities, by weight, based on the total weight of the vehicle. The impurities can comprise, for example, liquid organic contaminants having boiling points that are higher than the maximum boiling point of the vehicle.

According to yet other formulations of the present teachings, a film-forming formulation for inkjet and/or thermal printing is provided that comprises a film-forming material dispersed in a vehicle and comprising at least one pigment. The pigment exhibits an evaporation or a sublimation temperature and can have an average particle diameter of about 500 nm or less, for example, of 100 nm or less, of 90 nm or less, or of 80 nm or less. The pigment can be present in an amount of from about 0.1% by weight to about 5.0%, or from about 0.5% by weight to about 5.0% by weight, based on the total weight of the film-forming formulation, for example, in an amount of from about 0.5% by weight to about 3% by weight, from about 1% by weight to about 3% by weight, or at about 2% by weight, based on the total weight of the film-forming formulation. The pigment is substantially insoluble in the vehicle, for example, such that from only 0.5% by weight to 1.0% by weight of the pigment is dispersed in the vehicle, or less than 0.5% by weight of the pigment is dispersed in the vehicle. The film-forming material can comprise an ink.

In formulations comprising pigments or other insoluble film-forming materials, the vehicle can have a maximum boiling point that is at least 50° C. lower than the evaporation or sublimation temperature of the film-forming material, for example, at least 55° C. lower, at least 60° C. lower, at least 65° C. lower, or at least 70° C. lower. The film-forming formulation can have a surface tension of from about 28 dynes/cm to about 40 dynes/cm, for example, from about 33 dynes/cm to about 39 dynes/cm, or from about 35 dynes/cm to about 37 dynes/cm. The formulation can have a viscosity at inkjet printing temperatures of from about 1.0 centipoise to about 15 centipoise, for example, from about 6.0 centipoise to about 12 centipoise, or from about 4.0 centipoise to about 10 centipoise. The vehicle can be substantially pure such that when heated to a temperature between the boiling point and the evaporation or sublimation temperature the vehicle substantially completely evaporates while the film-forming material remains stable.

For formulations wherein the film-forming material is insoluble in the vehicle, the film-forming material can comprise one or more components useful in forming at least one of a hole transport layer, a hole injection layer, an electron transport layer, an electron injection layer, and an emissive layer, of an organic light-emitting device. The film-forming material can consist of a single organic compound, for example, a single pigment. In some embodiments, a pigment is used that comprises a dopant and a host, for example, wherein the dopant is present in an amount of from about 2% by weight to about 20% by weight based on the total weight of the film-forming material, and the host is present in an amount of from about 80% by weight to about 98% by weight based on the total weight of the film-forming material. The film-forming material can consist of or consist essentially of the dopant and the host. In an exemplary formulation, the film-forming material comprises a dopant present in an amount of from about 1% by weight to about 10% by weight based on the total weight of the film-forming material, and a host is present in an amount of from about 90% by weight to about 99% by weight based on the total weight of the film-forming material.

For formulations wherein the film-forming material is soluble in the vehicle, the vehicle can comprise pyrrolidinone, methylpyrrolidinone, anisole, methylbenzoate, methyl naphthalene, or a combination thereof. In another example, the vehicle can comprise methyl naphthalene and phenoxy ethanol. The vehicle can be substantially or highly pure, for example, such that it contains 2000 ppm or less of impurities, by weight, based on the total weight of the vehicle. The impurities can comprise liquid organic contaminants, for example, those having boiling points that are higher than the maximum boiling point of the vehicle.

In yet other embodiments of the present teachings, a method for evaluating a film-forming formulation for an inkjet and/or thermal printing process is provided. The method can comprise formulating a film-forming formulation comprising a film-forming material dissolved in a vehicle. The film-forming material can comprise at least one organic compound and the material can have an evaporation or a sublimation temperature. The film-forming material can be present in an amount of from about 0.1% by weight to about 5.0% by weight based on the total weight of the film-forming formulation, for example, in an amount of from about 0.2% by weight to about 3% by weight, from about 1% by weight to about 3% by weight, or at about 2% by weight, based on the total weight of the film-forming formulation. The method can comprise making a number of determinations to test whether the formulation would be useful for inkjet and/or thermal printing, for example, to make a layer for an organic light emitting device. The determinations can include, for example, determining (1) that the film-forming material is substantially soluble in the vehicle, and determining (2) that the vehicle has a maximum boiling point and the maximum boiling point is lower than the evaporation or sublimation temperature of the film-forming material by at least 50° C., for example, at least 55° C. lower, at least 60° C. lower, at least 65° C. lower, or at least 70° C. lower. The method can comprise determining (3) that the film-forming formulation has a surface tension and the surface tension is in the range of from about 28 dynes/cm to about 40 dynes/cm at 25° C., for example, from about 33 dynes/cm to about 39 dynes/cm at 25° C., or from about 35 dynes/cm to about 37 dynes/cm at 25° C. The method can comprise determining (4) that the film-forming formulation has a viscosity and the viscosity is in the range of from about 3.0 centipoise to about 15 centipoise, for example, from about 2.0 centipoise to about 12 centipoise, or from about 4.0 centipoise to about 10 centipoise, at an inkjet jetting temperature, for example, at room temperature or 25° C. The method can further comprise heating the film-forming formulation to a temperature between the boiling point and the evaporation or sublimation temperature and determining (5) that the vehicle substantially completely evaporates at the temperature while the film-forming material is stable. If it is determined that each of criteria (1)-(5) are met by the formulation, the formulation can be labeled acceptable or otherwise to indicate it is a good candidate for inkjet and/or thermal printing. The method can also comprise packaging the film-forming formulation for use or sale.

In some embodiments, a testing method is provided that further comprises testing the purity of the vehicle to determine (6) that the vehicle has a purity and the purity is measured as having 2000 ppm or less impurities based on the total weight of the vehicle. The purity can be tested, for example, by subjecting a sample of the vehicle to gas chromatography, mass spectroscopy, or a combination thereof. In some methods, the film-forming formulation is used in a thermal printing process after making determinations (1)-(6) and confirming that the criteria are met by the formulation. Using the film-forming formulation can comprise first printing the film-forming formulation, for example, inkjet printing the film-forming formulation onto a thermal printing printhead. The method can then comprise heating the film-forming formulation on the thermal printing printhead to a temperature between the boiling point and the evaporation or sublimation temperature to form a dried film-forming material on the thermal printing printhead. The method can then comprise thermal printing the dried film-forming material to form a film. The film can comprise, for example, a hole transport layer, a hole injection layer, an electron transport layer, an electron injection layer, or an emissive layer, emitting layer, or emission layer of an organic light-emitting device.

The determinations can instead include more specific criteria, for example, determining whether the film-forming material is present in an amount of from about 1.0% by weight to about 3.0% by weight based on the total weight of the film-forming formulation, and/or determining whether the film-forming formulation has a surface tension of from about 35 dynes/cm to about 37 dynes/cm. The step of determining viscosity can determine whether the formulation has a viscosity of from about 6.0 centipoise to about 12 centipoise at an inkjet jetting temperature, for example, at room temperature or 25° C.

Layers of a panel display deposited or to be deposited can include “structured layers,” “structured thin films” or simply “layers” or “thin films.” The materials and methods of the present teachings can be applied to document and image creation as well as the manufacture of thin film electronic devices and/or optoelectronic devices such as thin film transistors, flat panel displays, light emitting diodes “LEDs,” LEDs based upon organic molecules or polymers, “OLEDs,” among others.

According to various embodiments of the present teachings, a method is provided that can apply structured layers on a substrate to provide a desired pattern of components on the substrate. The method can comprise the computer-controlled transfer of organic material from a printhead onto a substrate.

Advantages and disadvantages of various inkjet techniques are described, for example, in “The Chemistry of Inkjet Inks” S. Magdassi, Ed. (World Scientific Publishing, 2010) (hereinafter “Magdassi”), particularly Chapter 1. The entire contents of Magdassi is incorporated herein in its entirety by reference, for all purposes.

Inkjet procedures of the present teachings can use an inkjet film-forming formulation suitable to a given procedure. For example, inkjet methods can be used that are described in Magdassi (supra), “The Printing Ink Manual Fifth Ed.”, R. H. Leach, R. J. Pierce Eds. (Kluwer Academic Publishers, 1999), and in U.S. Pat. No. 7,803,852 B2, which are incorporated herein in their entireties by reference. According to various embodiments of the present teachings, thermal printing formulations are formulated so that the pores of a thermal printing printhead can receive and hold the formulation ejected from an inkjet discharge device.

According to various embodiments of the present teachings, a printing process that can be used with the formulations described herein comprises a three-stage process for forming patterned layers on substrates. The first stage can comprise ejecting suitable film-forming formulation from an inkjet nozzle. Such droplets emerging from the inkjet head impact a thermal printing printhead transfer surface that can contain pores into which the formulation flows. A second stage in the process can involve the removal of vehicle from the formulation while the formulation resides in or on the thermal printing printhead, typically by the application of heat from a heater in thermal communication with the pores of the thermal printing printhead containing or retaining the formulation. The third stage of the process can comprise the further heating of the substantially dry film-forming material in the pores of the thermal printing printhead, causing the film-forming material to leave the pores by a process of sublimation and/or melting and evaporation. This process is an example of a thermal printing process as referred to herein. During movement of the thermal printing printhead over the substrate, the film-forming material, without vehicle, can be deposited onto the substrate in the desired pattern, avoiding the dangers a vehicle or solvent might pose to already-deposited layers on the substrate.

Exemplary embodiments of a thermal printing system technology are described in Bulovic et al., U.S. Patent Application Publication No. US 2008/0308037 A1, published Dec. 18, 2008 (“Bulovic et al.”), which is incorporated herein in its entirety by reference.

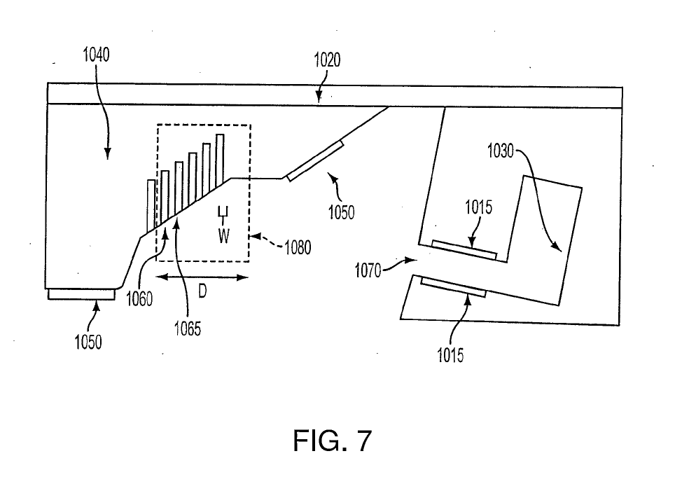

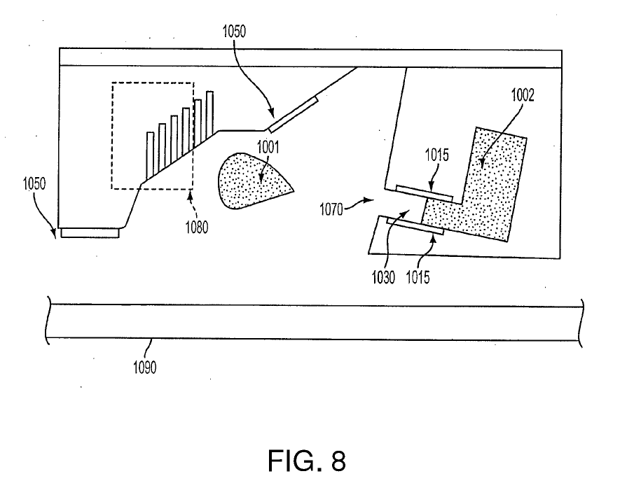

According to various embodiments, and with reference to FIGS. 7 and 8, FIG. 7 is a schematic representation of an exemplary printhead. The exemplary apparatus shown in FIG. 7 for depositing a material on a substrate comprises chamber 1030 for housing ink with containing particles of material to be deposited on a substrate suspended or dissolved in a carrier liquid. Chamber 1030 includes orifice 1070 and a delivery path from orifice 1070 to a discharge nozzle 1080. Discharge nozzle 1080 is defined by a surface that may contain a plurality of micro-porous conduits 1060 for receiving the material communicated through orifice 1070 from chamber 1030. These conduits extend into, but not through, supporting material 1040 which provides mechanical support for the discharge nozzle 1080. Housing 1040 may be joined to the housing for chamber 1030 using bracket or connecting material 1020.

Chamber activator 1015 also includes a piezoelectric actuator 1015 coupled to chamber 1030 for providing pulsating energy to activate the ink dispensing mechanism and thereby meter a droplet of the liquid from chamber 1030 through orifice 1070 towards discharge nozzle 1080. The pulsating energy can be variable on a time scale of one minute or less. For instance, the piezoelectric actuator 1015 can be energized with square pulses having a variable duty cycle and a cycle frequency of 1 kHz. Chamber 1030 may contain material required for forming a film used in the fabrication of an OLED or a transistor. Orifice 1070 is configured such that surface tension of the liquid in chamber 1030 prevents discharge of the liquid prior to activation of the piezoelectric ink dispensing mechanism.

Discharge nozzle 1080 may include rigid portions (interchangeably, partitions) 1065 separated by micro-pores 1060. The micro-pores region can be composed of a variety of materials, such as micro-porous alumina or solid membranes of silicon or silicon carbide and having micro-fabricated pores. In one embodiment, micro-pores 1060 receive the material dissolved or suspended in the liquid and prevent the material from being released again from discharge nozzle 1080 until the medium is appropriately activated. Discharge nozzle 1080 may also comprise a rough surface (not shown) for receiving the material dissolved or suspended in the carrier liquid and delivered from chamber orifice 1070. The surface can similarly contain the material until the discharge nozzle is properly actuated. Alternatively, discharge nozzle 1080 may comprise a smooth surface (not shown) for receiving the material dissolved or suspended in the liquid and delivered from chamber orifice 1070. The smooth surface can be adapted to contain the material until the discharge nozzle is properly actuated. Such adaptations can comprise modification of the surface chemistry or proper selection of the discharge nozzle material with respect to the choice of liquid.

In the exemplary device of FIG. 7, when the discharged droplet of liquid encounters discharge nozzle 1080, the liquid is drawn into micro-pores 1060 with the assistance of the capillary action. The liquid in the ink may evaporate prior to activation of discharge nozzle 1080, leaving behind a coating of the suspended or dissolved material on the micro-pore walls. The evaporation of the liquid in the ink may be accelerated by heating discharge nozzle 1080. The evaporated liquid can be removed from the chamber and subsequently collected (not shown) by flowing gas over one or more of the discharge nozzle faces.

Depending on the desired application, micro-pores 1060 can provide containers having a maximum cross-sectional distance W of a few nanometers to hundreds of microns. The micro-porous region comprising discharge nozzle 1080 will take a different shape and cover a different area depending on the desired application, with a typical dimension D ranging from a few hundred nanometers to tens of millimeters. If discharge nozzle 1080 is adapted so that the micro-porous region is replaced by a roughened surface region or a smooth surface region (not shown), the discharge nozzle 1080 behaves in substantially the same manner, whereby the material delivered in a liquid from the chamber 1030 to discharged nozzle 1080 is retained on the surface (by surface tension through proper control of surface and material properties) until activation of discharge nozzle 1080. The evaporation of the liquid in the ink may be accelerated by heating the discharge nozzle. Again, the evaporated liquid can be removed from the chamber and subsequently collected (not shown) by flowing gas over one or more of the discharge nozzle faces.

In the exemplary apparatus of FIG. 7, the relative orientation of the chamber nozzle orifice 1070 and the surface of discharge nozzle 1080 are such that the liquid in chamber 1030 can be delivered directly from the chamber orifice 1070 (for instance, by firing a droplet at a controlled velocity and trajectory out of chamber orifice 1070) onto the discharge nozzle surface. Furthermore, the discharge nozzle surface is also positioned such that when activated, the material delivered to the discharge nozzle surface can flow substantially towards the substrate. In the exemplary embodiment of FIG. 7, this is accomplished by aligning the discharge nozzle surface to an intermediate angle relative to both the incoming trajectory of the liquid supplied through chamber orifice 1070 and the angle of the substrate, which would be placed below the printhead (shown in FIG. 8).

Also, in the exemplary embodiment of FIG. 7, the discharge nozzle is activated by heater 1050 which is positioned proximal to the discharge nozzle 1080. Nozzle heater 1050 may comprise a thin metal film, composed of, for instance, platinum. When activated, nozzle heater 1050 provides pulsating thermal energy to discharge nozzle 1080, which dislodges the material contained within micro-pores 1060 allowing the material to flow out from the discharge nozzle. Dislodging the material may include vaporization of the substantially solid particles, either through sublimation or melting and subsequent evaporation. In general, one can employ any energy source coupled to the discharge nozzle capable of energizing discharge nozzle 1080 and thereby discharging the material from micro-pores 1060. For example, mechanical (e.g., vibrational) energy may be used.

FIG. 8 illustrates a method for depositing a film using the printhead shown in FIG. 7. The method of FIG. 8 is referred to herein as a thermal printing method. Referring to FIG. 8, chamber 1030 is commissioned with ink 1002, comprising particles or molecules of material to be deposited on a substrate, dissolved, or suspended in a carrier liquid. Piezoelectric elements 1015 pulsatingly meter liquid 1002 as it travels from chamber 1030 through orifice 1070 to form free droplet 1001. In an alternative embodiment (not shown), a heater is positioned in place of piezoelectric element 1015 for pulsatingly activating a thermal ink dispensing mechanism and thereby driving at least a portion of liquid 1002 in chamber 1030 through orifice 1070 to form free droplet 1001. In general, any pulsating energy source that activates the ink dispensing mechanism to thereby meter liquid 1002 as it travels through orifice 1070 towards discharge nozzle 1080 can be utilized. The intensity and the duration of each energy pulse can be defined by a controller (not shown).

Referring to FIG. 8, discharge nozzle heater 1050 may be activated so that the discharge nozzle temperature is elevated above ambient temperature. The heating cycle assists in rapidly evaporating the liquid in the ink after it is deposited on the discharge nozzle. Discharge nozzle heater 1050 may also be activated prior to energizing the ink dispensing mechanism (and discharging ink droplet 1001 from chamber 1030 through orifice 1070) or after droplet 1001 lands on discharge nozzle 1080.

In some embodiments, other forms of heating, such as radio frequency (RF), microwave heating, or laser heating can be used to drive off vehicle.

In some embodiments, deposition on the substrate comprises or consists of inkjet printing with no transfer to a thermal printing printhead. If deposition comprises direct transfer from an inkjet printhead directly to the substrate, vehicle can be evaporated without substantially heating the layer deposited.

The dry film-forming material in the thermal printing printhead transfer surface can be transferred from the transfer surface to be deposited on the substrate. This process can be conveniently carried out with a further heating step to a temperature in excess of that used to drive off vehicle. The film-forming material is thereby caused to leave the thermal transfer surface by this subsequent heating step either by melting and evaporation or by direct sublimation into the vapor phase. The process driving off the film-forming material from the thermal printing printhead transfer surface can comprise sublimation, melting, evaporation, or a combination thereof, for transfer onto a substrate.

Film-forming formulations can be “jettable,” forming droplets that deposit on the thermal printing nozzle and flow into the pores of the thermal printing printhead transfer surface. Viscosity and surface tension are parameters in jettability specific for inkjet printheads. For example, for various piezo inkjet printheads ink viscosities from about 2 centipoise (cPs) to about 15 cPs, or from about 4 cPs to about 12 cPs, or from about 6 cPs to about 10 cPs, at 25° C. For example, formulation surface tensions from about 26 dynes/cm to about 45 dynes/cm at 25° C. or from about 35 dynes/cm to 37 dynes/cm at 25° C., can be used.

A film-forming formulation droplet can contain adequate amounts of the film-forming material to provide sufficient dry material in thermal printing printhead pores for subsequent evaporation and/or sublimation. The film-forming material can be dissolved in at least one vehicle of the droplet or dispersed throughout the liquid of the droplet in the form of small particles. In some embodiments either a solution or dispersion is capable of giving adequate performance in a thermal printing system (subject to meeting other criteria as described herein). For dispersions of substantially insoluble materials, the particles can have a relatively narrow size distribution, for example, generally less than about 150 nanometers (nm) in average particle diameter, to be stable and inkjettable. Dispersions can have a shelf life greater than about six months.

Reference herein to film-forming material “dissolved” in the vehicle of the droplet to form a “solution” includes cases in which a dispersion rather than an actual solution is used.

The overall performance of an inkjet and/or thermal printing process, and the properties of the film produced on the substrate, can be influenced by impurities in the film-forming formulation. Impurities can be present in the vendor-supplied vehicle or can come from other components. Impurities can also be introduced during handling or use of the formulation during the printing process. For example, purities greater than from about 99.0% by weight to about 99.9% by weight can be used, based on the total weight of the formulation. Achieving this level of purity can involve purification of as-supplied vehicles or formulations or components as well as adequate precautions to avoid impurities introduced during the inkjet and/or thermal printing processes. Any suitable purification process can be used.

The vehicle component of the droplets can be removed at temperatures below the evaporation or sublimation temperature of the film-forming material. A difference of from about 25° C. to about 75° C., from about 35° C. to about 60° C., from about 45° C. to about 50° C., or greater than about 75° C. between the vehicle boiling point and the evaporation or sublimation point of the film-forming material can be used. Vehicles used for OLED depositions can have boiling points from about 70° C. to about 300° C., from about 240° C. to about 255° C., or from about 250° C. to about 260° C., while evaporation or sublimation temperatures are typically in the range from about 250° C. to about 500° C., or from about 350° C. to about 450° C.

Nothing herein restricts the film-forming material(s) to a single chemical species either dissolved or dispersed in a single solvent or in a mixture of solvents. The physical and chemical criteria described herein (e.g. viscosity, boiling points, evaporation and/or sublimation temperatures, surface tension, purity, and the like) apply to the mixture of film-forming material(s) and/or vehicles(s) as actually employed in the process.

The film-forming material can be expelled from the pores of the thermal printing nozzle or other transfer surface in the third process step, typically by the application of additional heat and higher temperatures. Sublimation can be used alone, in combination with, or as an alternative to, melting and evaporation.

In some embodiments, following the evaporation or sublimation step, no residue remains in the pores of the inkjet or thermal printing printhead so as not to interfere with subsequent transfer and deposition of the same or different materials. In some embodiments, some residue remains and the printheads, whether inkjet, thermal printing, or both, can be removed and replaced or cleaned in situ. Reducing or eliminating such residue is one desirable characteristic for the printing formulations of the present teachings.

If a thermal printing process is involved, it can be carried out with a variety of loading procedures. “Backside loading” can be used wherein the formulation is loaded onto the thermal printing nozzle and into the pores, from the side of the thermal printing nozzle opposite from the substrate onto which the material is to be printed. In some embodiments, “frontside loading” is employed in which the formulation is deposited onto the thermal printing nozzle from the same side of the nozzle from which the formulation is to be discharged. For example, thermal printing nozzles or other transfer surface mounted on a rotating wheel can be loaded with formulation from the frontside, then rotated into position adjacent to a substrate for discharge and formation of a desired patterned layer on the substrate.

### Inks and Processes for OLED Fabrication.

Fabrication by inkjet and/or thermal printing processes of various layers is useful in the fabrication of OLED devices. The procedures, materials, and formulations described herein in connection with OLED fabrication are not limited to any particular device, but instead have broader applicability in the fabrication of many types of patterned layers on substrates, as will be apparent to those having ordinary skill in the art.

### Vehicle Selection Criteria

A vehicle comprising a mixture of two or more solvents generally has a boiling point, surface tension, and viscosity that are different than those of any of the individual solvents in a neat or pure form. Such mixtures are also expected to have different properties than any of the individual solvents, with respect to solubility or dispersability of a film-forming material. Thus, in determining a suitable formulation for use in an inkjet and/or thermal printing process, mixtures of solvents can be used for vehicles as can vehicles comprising a single chemical solvent or species.

### Pre-Screening of Vehicles

It facilitates manufacturing a formulation suitable for depositing OLEDs (or other films), for example, by means of an inkjet and/or thermal printing process, to have screening criteria for pre-selecting vehicles that have properties likely to function adequately in the printing process. Chemical compatibility of the film-forming material and the vehicle is certainly an important feature of a successful formulation, but pre-screening the vehicle separate from a fully-formulated formulation can expedite the process by eliminating clearly unsuitable vehicle candidates. Vehicle pre-screening can include one or more of the following analyses: thermal analysis, analysis of fluid properties, wetting behavior, and purity. Thermal analysis can be used to ascertain the boiling point of a vehicle as well as the nature and amount of residue left upon evaporation. Analysis of fluid properties can include a determination of viscosity (typically employing a viscometer) and surface tension (typically employing a surface tensiometer). A thorough analysis can determine these fluid properties for a range of temperatures encompassing the temperatures the vehicle is expected to encounter during storage and use. Wetting behavior is used to estimate the spreading likely to be encountered when the vehicle is in contact with the surface materials it is expected to encounter during use, for example, silicon and silicon dioxide. A goniometric measurement of contact angle is typically adequate for this purpose. The purity of the vehicle can influence a printing process. Testing the purity of vehicles, for example, via gas chromatography and/or mass spectroscopy, is a pre-screening procedure that can be followed by additional purification of the vehicle. Presence in the vehicle of impurities having high boiling points can interfere with a subsequent (higher temperature) evaporation and/or sublimation process step.

A film-forming formulation suitable for use in a thermal printing process can have adequate properties for deposition onto a thermal printhead. The formulation characteristics appropriate for inkjet deposition are sometimes in conflict with the properties needed for the subsequent solids removal step, that is, the subsequent evaporation and/or sublimation step, used in some cases of the present teachings to deposit film-forming material, for example, OLED material, onto a substrate. For example, some vehicles and vehicle combinations for inkjet processes typically have a viscosity of about 11 cPs, a surface tension of about 35 dyne/cm, and a high boiling point (for example, of about 250° C.). This combination of physical properties typically enables reliable inkjet printing at high frequency and good latency. In some embodiments, a vehicle comprising a mixture of solvents can be used, for example, comprising about 10% by volume, 20% by volume, 30% by volume, or 40% by volume methyl naphthalene (MTNH) or methyl benzoate, about 50% by volume, 60% by volume, 70% by volume, or 80% by volume phenoxyethanol or anisole, and about 5% by volume, 10% by volume, 15% by volume, or 20% by volume amyl octanoate or methoxy propanol. In some embodiments, a vehicle comprising a mixture of 40% by volume, 50% by volume, 60% by volume, or 70% by volume benzyl alcohol, about 10% by volume, 15% by volume, 20% by volume, or 25% by volume pyrrolidinone, and about 10% by volume, 20% by volume, 30% by volume, or 40% by volume mineral oil, can be used. In some embodiments, vehicles comprising 50% by volume of each of two solvents can be used, for example, two-way mixtures of any two of tetrahydronaphthalene, ethylene glycol butyl ether, dimethyl formamide, dipropylene glycol methyl ether, terpineol, phenoxyethanol, and butyrophenone. Vehicles and combinations of vehicles having relatively low boiling points can also be used for thermal printing processes. For example, thermal printing formulations based on xylene, toluene, mesitylene, anisole, among others, including mixtures, can be used for thermal printing.

The following examples are intended to illustrate the advantages of various embodiments of the present teachings and are not limiting in any way.

### EXAMPLE

Table I lists materials that can be used in OLED constituent layers and also as candidate inkjet and/or thermal printing inks according to the present teachings. The solubilities of these OLED materials can depend greatly on the particular vehicle used. Solubility, surface tension, viscosity, purity, and boiling points are parameters that can be evaluated to determine the suitability of a particular vehicle or vehicle mixture, when used together with a particular film-forming material, to make a film-forming formulation useful for inkjet printing, for thermal printing, or for a two-step thermal printing process.

Typical examples of components for OLED layers are shown below in Table 1:

TABLE 1
Exemplary Components for OLED layers

```
HIL-Type (Hole Injection Layer)
  PEDOT /PSS—poly(3,4-ethylenedioxythiophene)-poly(styrene sulfonate)
  (PANI-PSS)—polyaniline-poly(styrene sulfonate)
  MTDATA—4,4′,4″-tris[N-(3-methylphenyl)-N-phenylamino]triphenylamine
  CuPc—copper phthalocyanine
HTL-Type (Hole Transport Layer)
  NPB (aka NPD)—N′-diphenyl-N,N′-bis(1-naphthyl)(1,1′-biphenyl)4,4′-
  diamine.
EML-Type: (Emissive Layer)
  Ir(ppy)3—Iridium, tris(2-phenylpyridine)
  BAlq3—bis(2-methyl-8-quinolinolato-N1,O8)-(1,1′-biphenyl-4-olato)
  aluminum
  Alq3—tris(8-quinolinolato)aluminum
HBL-Type (Hole Blocking Layer)
  BAlq3—bis(2-methyl-8-quinolinolato-N1,O8)-(1,1′-biphenyl-4-olato)
  aluminum
ETL—Type (Electron Transport Layer)
  Alq (aka Alq3)—tris(8-quinolinolato)aluminum
EIL—Type (Electron Injecting Type)
  LiF (Lithium Fluoride)
```

Many other OLED materials that can be used in connection with the present teachings include those described, for example, in U.S. Pat. Nos. 7,304,428 B2; 6,208,077; 6,208,075; 6,127,004; 5,503,910; 5,283,182; 4,356,429; 4,539,507; 4,720,432; 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721; and 6,020,078, which are incorporated herein in their entireties by reference.

All publications, patents, and patent applications mentioned in this specification are herein incorporated by reference to the same extent as if each individual publication, patent, or patent application was specifically and individually indicated to be incorporated by reference.

While embodiments of the present disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the disclosure described herein may be employed in practicing the disclosure. It is intended that the following claims define the scope of the disclosure and that methods and structures within the scope of these claims and their equivalents be covered thereby.

What is claimed is:

1. A film-forming formulation for inkjet printing, comprising a film-forming material dissolved in a vehicle, the film-forming material being stable in the vehicle and being present in an amount of from about 0.1% by weight to about 10.0% by weight based on the total weight of the film-forming formulation, wherein the vehicle comprises a blend of at least two solvents that are miscible with one another, each solvent being present in an amount of from about 1% by weight to about 99% by weight based on the total weight of the vehicle, the vehicle being formulated to substantially completely evaporate while the film-forming material forms a solid film, the film-forming formulation having a viscosity and a surface tension at an inkjet jetting temperature, which enable delivery from an inkjet printhead, wherein the vehicle exhibits an evaporation rate that differs from the evaporation rate of any one of the at least two solvents alone and the vehicle exhibits a surface tension that provides a substantially uniformly thick film of the film-forming material.

2. The film-forming formulation of claim 1, wherein the film-forming material comprises one or more components useful in forming at least one of a hole transport layer, a hole injection layer, an electron transport layer, an electron injection layer, and an emissive layer, of an organic light-emitting device.

3. The film-forming formulation of claim 1, wherein the film-forming material comprises no more than a single organic compound.

4. The film-forming formulation of claim 1, wherein the film-forming formulation exhibits a surface tension of 40.0 dynes/cm or lower at 25° C.

5. The film-forming formulation of claim 1, wherein the at least two solvents comprises at least two organic solvents.

6. The film-forming formulation of claim 1, wherein the at least two solvents comprises two or more solvents selected from pyrrolidinone, methylpyrrolidinone, anisole, alkyl benzoate, methylbenzoate, alkyl naphthalene, methyl naphthalene, alkoxy alcohol, methoxy propanol, phenoxy ethanol, amyl octanoate, cis-decalin, trans-decalin, mesitylene, alkyl benzene, butyl benzene, dodecyl benzene, alkyl alcohol, aryl alcohol, benzyl alcohol, butyrophenon, dipropylene glycol methyl ether, valerophenon, and 1,3-propanediol.

7. The film-forming formulation of claim 1, wherein the vehicle comprises a mixture of organic solvents and the film-forming material comprises organic small molecules useful for forming an emissive layer of an organic light emitting device.

8. The film-forming formulation of claim 1, wherein the film-forming material is present in an amount of from about 0.2% by weight to about 3% by weight based on the total weight of the film-forming formulation.

9. The film-forming formulation of claim 1, wherein the formulation exhibits a surface tension of from about 30 dynes/cm to about 37 dynes/cm.

10. The film-forming formulation of claim 1, wherein the formulation exhibits a surface tension of from about 34 dynes/cm to about 36 dynes/cm.

11. The film-forming formulation of claim 1, wherein the formulation exhibits a viscosity of from about 1.0 centipoise to about 14 centipoise at 25° C.

12. The film-forming formulation of claim 1, wherein the formulation exhibits a viscosity of from about 4.0 centipoise to about 10 centipoise at 25° C.

13. The film-forming formulation of claim 1, wherein the inkjet jetting temperature is room temperature.

14. The film-forming formulation of claim 1, wherein each of the at least two solvents is present in an amount of 30% by weight or more based on the total weight of the vehicle.

15. The film-forming formulation of claim 14, wherein the vehicle further comprises up to 30% by weight, based on the total weight of the vehicle, of a third solvent or a mixture of solvents, in addition to the at least two solvents.

16. The film-forming formulation of claim 1, wherein the at least two solvents are miscible with water and the vehicle further comprises water and a surfactant.

17. The film-forming formulation of claim 16, wherein the surfactant comprises a non-ionic fluorosurfactant present in an amount of from about 0.001% by weight to about 1.0% by weight based on the total weight of the vehicle.

18. The film-forming formulation of claim 17, wherein the film-forming material comprises a polymeric material useful for forming a hole transport layer or a hole injection layer of an organic light emitting device.

19. The film-forming formulation of claim 16, wherein the film-forming material comprises one or more of poly (3,4-ethylenedioxythiopene), poly(ethylene dioxythiophene)/poly(styrene sulfonic acid) (PEDOT/PSS), an aqueous solution of polyaniline/camphor sulfonic acid (PANI/CSA), PTPDES, Et-PIT-DEK, PPBA, or a combination thereof.

20. The film-forming formulation of claim 1, formulated such that the film-forming material completes a pixel, when inkjet-printed onto a substrate, having less of a coffee ring effect than the coffee ring effect that is caused by inkjet-printing substantially the same formulation onto the same substrate but wherein the formulation comprises only one of the at least two solvents.

21. A system comprising an inkjet printhead loaded with the film-forming formulation of claim 1, wherein the film-forming formulation and the inkjet printhead are inert with respect to one another.

22. The system of claim 21, wherein the film-forming formulation does not dry on the inkjet printhead within 5 minutes after printing.

23. A method comprising:
inkjet printing the film-forming formulation of claim 1 onto a pixelated substrate to form a plurality of wet pixels; and
causing the vehicle in the wet pixels to evaporate thereby forming a plurality of completed pixels each having a substantially uniform thickness and exhibiting less of a coffee ring effect than the coffee ring effect that would be caused by inkjet-printing substantially the same formulation onto the same substrate but wherein the formulation comprises only one of the at least two solvents.

24. The method of claim 23, wherein each pixel of the plurality of pixels has a ratio of minimum thickness to maximum thickness of 0.9 or greater to 1.

25. The method of claim 23, wherein each of the plurality of pixels has a ratio of minimum thickness to maximum thickness of 0.95 or greater to 1.

26. The method of claim 23, wherein the pixelated substrate comprises an indium tin oxide glass material.

27. The method of claim 23, wherein the plurality of pixels comprises at least one of a hole transport layer, a hole injection layer, and an emissive layer, of an organic light-emitting device.

28. A method comprising:
inkjet printing the film-forming formulation of claim 1 onto a pixelated substrate to form a plurality of wet pixels; and
causing the vehicle in the wet pixels to evaporate thereby forming a plurality of completed pixels each having a substantially uniform thickness and exhibiting less pile-up, less overspill, and greater pinning than the pile-up, overspill, and pinning that would be caused by inkjet-printing substantially the same formulation onto the same substrate but wherein the formulation comprises only one of the at least two solvents.

29. A method for evaluating a film-forming formulation for an inkjet printing process, the method comprising:
forming a film-forming formulation comprising a film-forming material dissolved in a vehicle, the film-forming material being stable in the vehicle and being present in an amount of from about 0.1% by weight to about 10.0% by weight based on the total weight of the film-forming formulation, wherein the vehicle comprises a blend of at least two solvents that are miscible with one another, each solvent being present in an amount of from about 1% by weight to about 99% by weight based on the total weight of the vehicle;
determining (1) that the film-forming material is substantially soluble in the vehicle;
determining (2) that the film-forming formulation exhibits a surface tension of from about 28 dynes/cm to about 40 dynes/cm;
determining (3) that the film-forming formulation exhibits a viscosity of from about 1.0 centipoise to about 14 centipoise at inkjet jetting temperatures;
inkjet printing the film-forming formulation and determining (4) that the vehicle substantially completely evaporates while the film-forming material forms a solid film; and
determining (5) that the film-forming material has formed a film of substantially uniform thickness,
whereby, after making determinations (1)-(5), identifying the film-forming formulation as suitable for an inkjet printing process.

30. The method of claim 29, further comprising using the film-forming formulation in an inkjet printing process after making determinations (1)-(5), to form a layer of pixels on a substrate, wherein each pixel exhibits substantially uniform thickness and less of a coffee ring effect than would be exhibited if substantially the same formulation were inkjet-printed onto the same substrate but wherein the formulation comprises only one of the at least two solvents.

31. The method of claim 30, wherein the using comprises inkjet printing the film-forming formulation and evaporating the vehicle to thereby form an emissive layer, a hole transport layer, or a hole injection layer, for an organic light emitting device.

32. The method of claim 29, further comprising using the film-forming formulation in an inkjet printing process after making determinations (1)-(5), to form a layer of pixels on a substrate, wherein each pixel exhibits substantially uniform thickness and less pile-up, less overspill, and greater pinning than the pile-up, overspill, and pinning that would be caused if substantially the same formulation were inkjet-printed onto the same substrate but wherein the formulation comprises only one of the at least two solvents.

33. The method of claim 29, wherein:
the film-forming material is present in an amount of from about 0.1% by weight to about 3.0% by weight based on the total weight of the film-forming formulation;
the determining (2) comprises determining that the film-forming formulation exhibits a surface tension of from about 35 dynes/cm to about 37 dynes/cm at 25° C.; and
the determining (3) comprises determining that the film-forming formulation exhibits a viscosity of from about 4.0 centipoise to about 10 centipoise at 25° C.

34. The method of claim 29, wherein the determining (5) comprises determining that the film-forming material has formed a film having a ratio of minimum thickness to maximum thickness of 0.9 or greater to 1.
